(19) United States
(12) Patent Application Publication
(10) Pub. No.: US 2003/0141597 A1
(43) Pub. Date: Jul. 31, 2003

(54) Semiconductor apparatus having contacts of multiple heights and method of making same

(76) Inventors: Theodore W. Houston, Richardson, TX (US); Abha R. Singh, Fairview, TX (US)

Correspondence Address: TEXAS INSTRUMENTS INCORPORATED, P O BOX 655474, M/S 3999, DALLAS, TX, 75265

(21) Appl. No.: 10/324,244

(22) Filed: Dec. 19, 2002

Related U.S. Application Data
(60) Provisional application No. 60/353,434, filed on Jan. 31, 2002.

(51) Int. Cl. H01L 23/48

(52) U.S. Cl. 257/758

(57) ABSTRACT

A semiconductor apparatus and method are provided. According to an embodiment, the apparatus includes a first contact extending from a first conductive element disposed in a substrate. A second contact extends from a second conductive element disposed in the substrate at least to a lower limit of a capacitor well. The capacitor well is formed in a pre-metal dielectric layer disposed on the substrate. The second contact is shorter than the first contact. The height of the capacitor structure may be substantially the same as the height of the pre-metal dielectric layer. A first metal layer is disposed on the pre-metal dielectric layer. Thus, the capacitor structure may extend from the lower limit of the capacitor well to the first metal layer. The first contact extends to the first metal layer.

### BACKGROUND OF THE INVENTION

Electronic devices may incorporate semiconductor elements such as, for example, dynamic random access memories (DRAMs). A semiconductor element may include a capacitor structure formed therein as part of the process of manufacturing the semiconductor element.

A known semiconductor apparatus includes a substrate with a source region and a drain region formed in the substrate. A pre-metal dielectric (PMD) layer is disposed on the substrate, source region, and drain region. A capacitor well is formed in the PMD layer above either the source region or the drain region. For example, the capacitor well may be formed above the drain region. The apparatus includes one or more contacts or contact assemblies. A first contact may connect the source region with a metal layer disposed on the PMD layer. A second contact may connect the drain region with the capacitor well. In the conventional apparatus, due to the manufacturing process, the first and second contacts have substantially the same height. Thus, the second contact typically extends far into the capacitor well.

Using a standard contact for connecting the capacitor to either the source region or the drain region presents a number of problems. For instance, a special contact is needed to minimize junction leakage at the junction of the source and/or drain region with the substrate. The leakage may be caused by the source and/or drain region being formed by implanting one doping type (e.g. n-type) into an oppositely-doped substrate (e.g., to form a p/n junction). Stresses in the silicon make these junctions leaky. Forming silicide on the surface can cause stress and thus more leakage.

Another problem with conventional structures is that the contact may occupy an inordinate amount of space within the capacitor well. Therefore, the semiconductor device may not be made as small as possible.

One approach toward attempting to solve at least some of these problems includes providing a contact for the capacitor structure that is shorter than the other contact, which connects the other of the source region or drain region to the first metal layer. This approach is shown, for example, in FIG. 1. FIG. 1 depicts a semiconductor apparatus 10 including a substrate 32 in which are formed a source region 34, a drain region 38, and an isolation region 42. A gate electrode 36 and a dummy gate 44 are also provided. A PMD layer 48 is disposed on substrate 32, source region 34, drain region 38, isolation region 42, gate electrode 36, and dummy gate 44. A capacitor well 22 is formed in the PMD layer 48. A capacitor structure is provided within the capacitor well. The capacitor structure includes a capacitor bottom plate 20, a capacitor dielectric 18, and a capacitor top plate 16. A first metal layer 12 is disposed on the PMD layer 48. A first contact 30 extends from source region 34 to a first level designated by dotted line 26. A second contact 40 extends from drain region 38 to a lower limit of capacitor well 22 to electrically connect source region 38 with the capacitor structure. A stacked contact 24 extends from an upper surface of first contact 30 to first metal layer 12. First contact 30 and stacked contact 24 cooperate to electrically connect source region 34 with first metal layer 12. First metal layer 12 may function as a bit line layer.

During the process of manufacturing the semiconductor apparatus shown in FIG. 1, PMD layer 48 is formed in various stages or levels, which are identified by dotted lines 26 and 14. In a first stage, an initial dielectric layer is provided to a level extending roughly to the location of dotted line 26. The first and second contacts are then provided. During a subsequent step, a second level of a dielectric is provided on the first level to extend roughly to the location of dotted line 14. Then, the capacitor well is formed and a capacitor structure is formed in the capacitor well. A first or lower portion of stacked contact 24 may also be formed. In a subsequent step, a third level of dielectric is provided on the second level of dielectric. The first, second, and third levels of dielectric collectively form the PMD layer 48.

This process results in several disadvantages. For instance, the first contact does not extend all the way from the source region to the first metal layer. Rather, an additional contact structure, such as stacked contact 24, is required to electrically connect source region 34 with first metal layer 12. Also, second contact 40 only extends to the lower limit of capacitor well 22. Thus, no variation is allowed for the height of second contact 40. Also, the top of the capacitor structure is not adjacent to the first metal layer. In other words, the capacitor structure does not extend through the entire thickness of the PMD layer, and the capacitor structure does not have the same height as the PMD layer. Among other things, this configuration results in incompatibilities with a logic process flow in which the semiconductor apparatus is incorporated.

Other shortcomings of known structures and methods will be recognized by those having ordinary skill in the art.

### SUMMARY OF THE INVENTION

Among other things, the present invention provides a semiconductor apparatus and a method of making the apparatus which address the problems associated with prior devices and methods.

According to an example embodiment, a semiconductor apparatus includes a substrate, a first conductive element, and a second conductive element. A pre-metal dielectric layer is disposed on the substrate and has a capacitor well formed therein. The capacitor well extends from an upper limit to a lower limit. A first contact is provided and extends within the pre-metal dielectric layer from the first conductive element to a level substantially co-extensive with the upper limit of the capacitor well. A second contact is provided and extends within the pre-metal dielectric layer from the second conductive element at least to the lower limit of the capacitor well. The second contact is shorter than the first contact.

According to another example embodiment, a method of manufacturing a semiconductor apparatus is provided. According to the method, a substrate is provided. A first conductive element is provided in the substrate. A second conductive element is provided in the substrate. A pre-metal dielectric layer is provided on the substrate. A capacitor well is formed in the pre-metal dielectric layer. A first metal layer is provided on the pre-metal dielectric layer. A first contact is provided and extends from the first conductive element to the first metal layer. A second contact is provided and extends from the second conductive element at least to a lower limit of the capacitor well. The second contact is shorter than the first contact.

The various embodiments of the present invention provide certain technical advantages. Any particular embodiment may provide some, none or all of the following technical advantages.

One technical advantage is a reduction in junction leakage. Another technical advantage is a reduction in the volume occupied by the capacitor well. Another technical advantage is providing a capacitor structure in a semiconductor apparatus in which the capacitor structure has a height corresponding to a predetermined thickness for a pre-metal dielectric layer according to a logic process flow in which the semiconductor apparatus may be incorporated.

Other technical advantages will be apparent to one having ordinary skill in the art.

### BRIEF DESCRIPTION OF THE DRAWINGS

For a more complete understanding of particular embodiments of the invention and their advantages, reference is now made to the following descriptions, taken in conjunction with the accompanying drawings, in which:

FIG. 1 depicts a semiconductor apparatus having a capacitor structure in accordance with the prior art;

FIG. 2 depicts a semiconductor apparatus having a capacitor structure in accordance with an embodiment of the present invention;

FIG. 3 depicts a top, cross-sectional view of the apparatus depicted in FIG. 2;

FIG. 4 depicts a semiconductor apparatus having a capacitor structure in accordance with an embodiment of the present invention;

FIG. 5 depicts a top, cross-sectional view of the apparatus depicted in FIG. 4;

FIG. 6 depicts a step in a method of making a semiconductor apparatus having a capacitor structure in accordance with an embodiment of the present invention;

FIG. 7 depicts a step in a method of making a semiconductor apparatus having a capacitor structure in accordance with an embodiment of the present invention;

FIG. 8 depicts a step in a method of making a semiconductor apparatus having a capacitor structure in accordance with an embodiment of the present invention;

FIG. 9 depicts a step in a method of making a semiconductor apparatus having a capacitor structure in accordance with an embodiment of the present invention;

FIG. 10 depicts a step in a method of making a semiconductor apparatus having a capacitor structure in accordance with an embodiment of the present invention;

FIG. 11 depicts a step in a method of making a semiconductor apparatus having a capacitor structure in accordance with an embodiment of the present invention; and

FIG. 12 depicts a step in a method of making a semiconductor apparatus having a capacitor structure in accordance with an embodiment of the present invention.

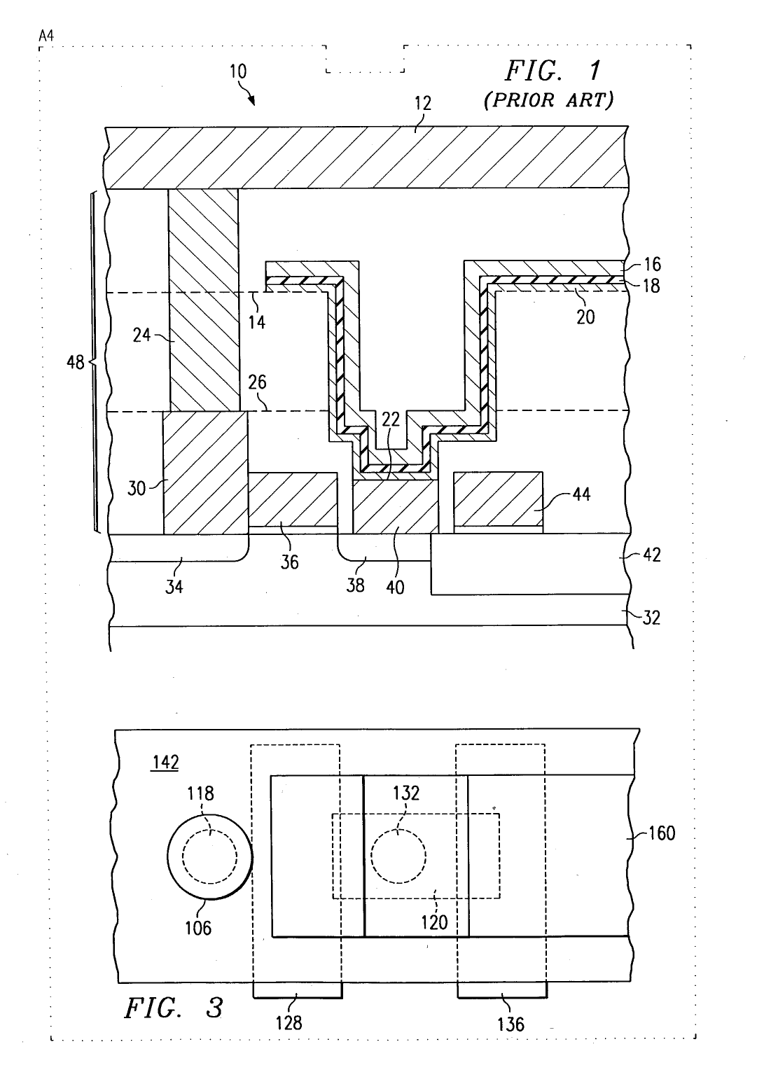

### DETAILED DESCRIPTION OF THE INVENTION

Among other things, various embodiments of the present invention may provide a semiconductor apparatus having a capacitor structure, and having contacts with multiple heights.

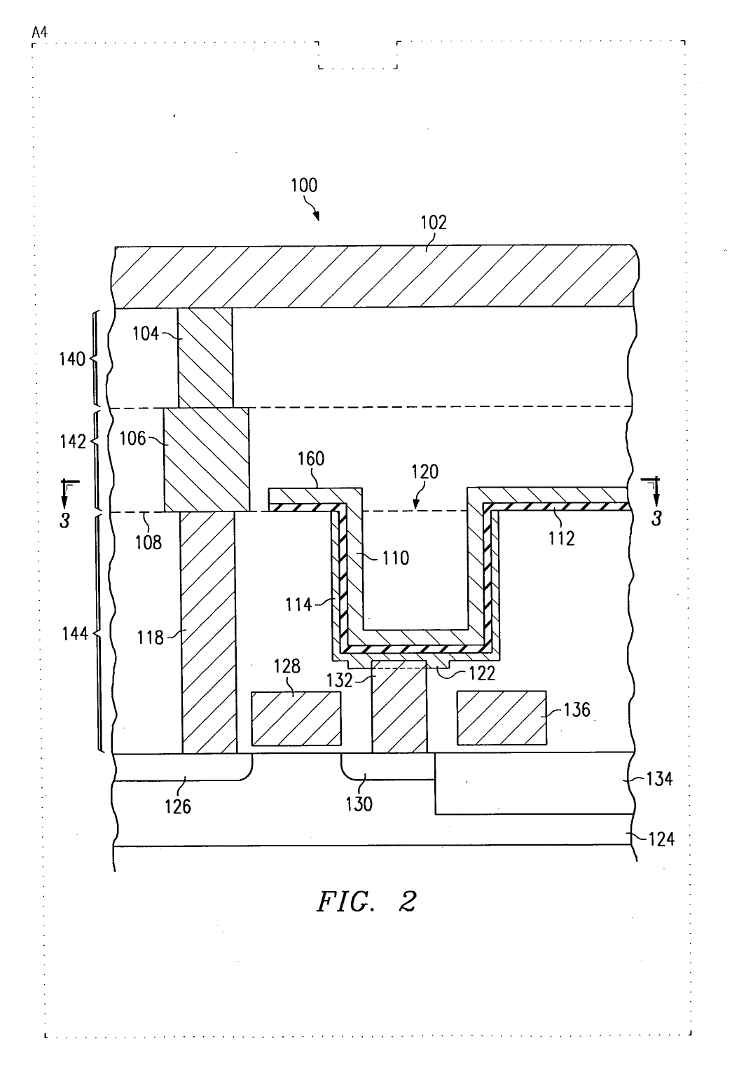

According to an embodiment depicted, for example, in FIGS. 2 and 3, a semiconductor apparatus 100 includes a substrate 124. Substrate 124 may be any suitable material including, without limitation, p-type silicon. Apparatus 100 also includes a first conductive element 126 and a second conductive element 130 disposed in substrate 124. First conductive element 126 may be, for example, a source region and second conductive element 130 may be, for example, a drain region. Depending upon the particular configuration of apparatus 100, each of first and second conductive elements 126 and 130 may be characterized as a source/drain region, depending upon the applicable voltages. First conductive element 126 may be formed from any suitable material including, without limitation, n-type silicon. Second conductive element 130 may be formed from any suitable material, including, without limitation, n-type silicon. Apparatus 100 further includes a first gate electrode 128 and a second gate electrode 136. The first and second gate electrodes 128, 136 may be formed from any suitable material, including, without limitation, polysilicon. Second gate electrode 136 may function as, for example, a dummy gate.

A pre-metal dielectric (PMD) layer 144 is disposed on substrate 124, first conductive element 126, second conductive element 130, first gate electrode 128, and second gate electrode 136. PMD layer 144 may be formed from any suitable material including, without limitation, silicon dioxide.

A capacitor well 120 is formed in PMD layer 144. The capacitor well 120 extends from an upper limit 108 to a lower limit 122. The upper limit 108 is substantially co-extensive with an upper limit of PMD layer 144.

A capacitor structure 160 is provided and at least partially disposed within capacitor well 120. Capacitor structure 160 includes a capacitor bottom plate 114, a capacitor dielectric layer 112, and a capacitor top plate 110. Capacitor bottom plate 114, capacitor dielectric layer 112, and a capacitor top plate 114, may be formed from any suitable materials.

As depicted in FIG. 2, the walls of capacitor well 120 are stepped near the lower limit thereof. FIG. 2 also depicts the capacitor bottom plate 114 being stepped in a similar manner to match the stepped portion of the walls of capacitor well 120. A lower surface of capacitor dielectric layer 112 is stepped to match the stepped portion of capacitor bottom plate 114. However, an upper surface of capacitor dielectric 112 is not stepped. Likewise, capacitor top plate 110 is not stepped. It will be recognized by those having ordinary skill in the art that the depicted capacitor structure is provided only as an example, and the various embodiments of the present invention may incorporate capacitor structures having other configurations.

A first metal layer 142 is disposed on PMD layer 144. First metal layer 142 may be, for example, a bit line layer. An inter-level dielectric layer 140 is disposed on first metal layer 142. A second metal layer 138 is disposed on interlevel dielectric layer 140. First metal layer 142, inter-level dielectric layer 140, and second metal layer 138 may be formed from any suitable materials.

A first contact 118 is provided within PMD layer 144 and extends from a first end to a second end. The first end is in contact with first conductive element 126. The second end is located at a level, which is substantially co-extensive with an upper limit of PMD layer 144. Preferably, first contact 118 electrically connects first conductive element 126 with first metal layer 142.

A second contact 132 is provided and also extends within PMD layer 144. Second contact 132 extends from a first end to a second end. The first end of second contact 132 is in contact with the second conductive element 130. The second end of second contact 132 preferably extends at least to lower limit 122 of capacitor well 120 to ensure contact to capacitor bottom plate 114. The second end of second contact 132 may extend above lower limit 122, and into capacitor well 120. Thus, lower limit 122 of capacitor well 120 may be located at a level between the first and second ends of second contact 132. Alternatively, the top of second contact 132 may be a little lower than lower limit 122, since the bottom plate material will fill in the contact opening during the manufacturing process. In any case, the second end of contact 132 should be covered by the bottom plate material and preferably does not extend into capacitor dielectric layer 112. Thus, second contact 132 is shorter than first contact 118.

Having two contact structures, one of which is for contact to second conductive element 130 (e.g., a DRAM storage node), allows one contact structure (e.g., first contact 118) to be optimized for logic (e.g. for yield or low resistance) and the other contact structure (e.g., second contact 132) to be optimized for low leakage.

A via 104 and an element 106 of first metal layer 142 cooperate to form a via-contact stack, which electrically connects the second end of first contact 118 with second metal layer 138. Element 106 preferably extends through first metal layer 142 substantially from a lower limit of first metal layer 142 to an upper limit of first metal layer 142. Via 104 preferably extends through inter-level dielectric layer 140 substantially from a lower limit of inter-level dielectric layer 140 to an upper limit of inter-level dielectric layer 140.

First contact 118 may be formed from any suitable material, including, without limitation, tungsten. First contact 118 may be a silicided contact. Second contact 132 may be formed from any suitable material including, without limitation, polysilicon. Preferably, second contact 132 is an unsilicided contact.

Standard contacts (e.g., with a tungsten plug) rely on having a silicided surface. For an unsilicided surface, the preference for a contact is a polysilicon plug. One result is a higher resistance contact, which is not desirable for logic circuits. Therefore, it is desirable to have one type of contact to the DRAM storage node, and a different type of contact for the rest for the circuit. The ability to contact to an unsilicided silicon surface reduces leakage.

According to this embodiment, an upper limit of the capacitor structure 160 is located substantially at the level of an upper limit of PMD layer 144, and the lower limit of first metal layer 142. Therefore, the capacitor structure extends to a height, which is substantially equivalent to the height of PMD layer 144. Among other things, this provides a semiconductor apparatus having a capacitor structure within a PMD layer that corresponds to a predetermined thickness for a PMD layer in a logic flow, which may incorporate the semiconductor apparatus.

FIG. 3 depicts a top, cross-sectional view of apparatus 100 taken along lines 3-3 of FIG. 2. First conductor 118 is shown within PMD layer 144. First and second gate electrodes 128, 136 are depicted. Capacitor well 120 is shown formed in PMD layer 144, as is second contact 132. Capacitor structure 160 is also depicted.

It should be noted that the various concepts presented in this embodiment are intended as examples. Other semiconductor configurations may incorporate various inventive aspects of this and other embodiments of the present invention. Among other things, the configuration of apparatus 100 enables the flow for manufacturing apparatus 100 to correspond to, and be compatible with, a logic flow that incorporates apparatus 100.

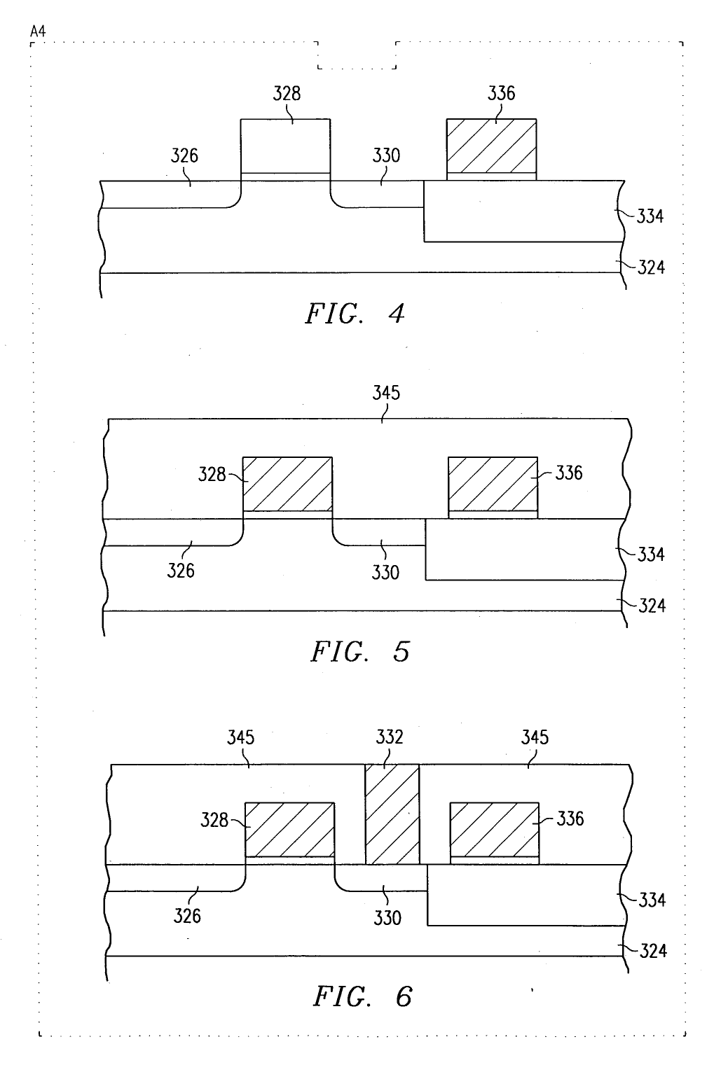

According to another embodiment of the present invention, a method is provided for making a semiconductor apparatus, which has a capacitor structure and contacts having multiple heights. This embodiment will be discussed in connection with FIGS. 4 through 12.

As shown in FIG. 4, in a first step of the method, a substrate 324 is provided. A first conductive element 326 such as, for example, a source/drain region, is formed in substrate 324. A second conductive element 330 such as, for example, a source/drain region (e.g., a DRAM storage node), is formed in substrate 324. An isolation region 334 is formed in substrate 324. A gate electrode 328 is formed on substrate 324. A dummy gate 336 may also be formed on substrate 324. Substrate 324, first conductive element 326, second conductive element 330, isolation region 334, gate electrode 328, and dummy gate 336 may all be formed by suitable semiconductor apparatus manufacturing techniques.

As shown in FIG. 5, a first level 345 of a pre-metal dielectric layer is formed on substrate 324, first conductive element 326, second conductive element 330, isolation region 334, gate electrode 328, and dummy gate 336. First level 345 of the PMD layer may be formed by depositing and planarizing a dielectric material. Preferably, first level 345 of the PMD layer is deposited and planarized to a depth approximately equal to the depth of the gate electrode. Preferably, the dielectric material is first deposited to a depth slightly greater than the depth of the gate electrode, and then planarized by chemical-mechanical polish (CMP), for example, and optionally further etched back to the depth which is approximately equal to the depth of the gate electrode. Optionally, the dielectric material may be etched back to below the depth of the gate electrode. The initial depth of the dielectric prior to the CMP and etch-back process may be chosen to reduce physical stress on the gate electrode from the CMP process. Alternatively, the dielectric may be formed of multiple layers of materials with selective etch characteristics, the surface of one of the layers being at the depth desired for a contact from second conductive element 330 to a capacitor bottom plate of a capacitor structure, with additional layers to provide a depth for planarization without stress to the gate electrode. Then, following formation of the contact opening, the layers of dielectric above the layer with the top surface at the desired depth are removed.

An etch-stop layer (not shown) may be provided within the PMD layer (e.g., within the first level 345 of the PMD material) to protect the gate 328 when the PMD material is being etched to form the capacitor well 320, as described below.

As shown in FIG. 6, contact 332 is provided. Preferably, contact 332 is formed by patterning and etching a contact opening, depositing contact material in the contact opening, and planarizing the contact material to a level that is substantially equal to the upper limit of the first level 345 of the PMD layer. To avoid stress of the gate electrode, planarization of the contact material is preferably performed by an etch-back process rather than a CMP process. In certain cases, a CMP process may be preferable for planarizing materials in a semiconductor apparatus. However, in this step perfect planarization at the top of the contact is not critical. The contact material can be etched back to a level below the outer dielectric surface and still have the capacitor bottom plate make contact to the contact material. This results from either the well etch removing dielectric down to or beyond the top level of the contact material, or from the bottom plate material extending down into the unfilled portion of the contact opening.

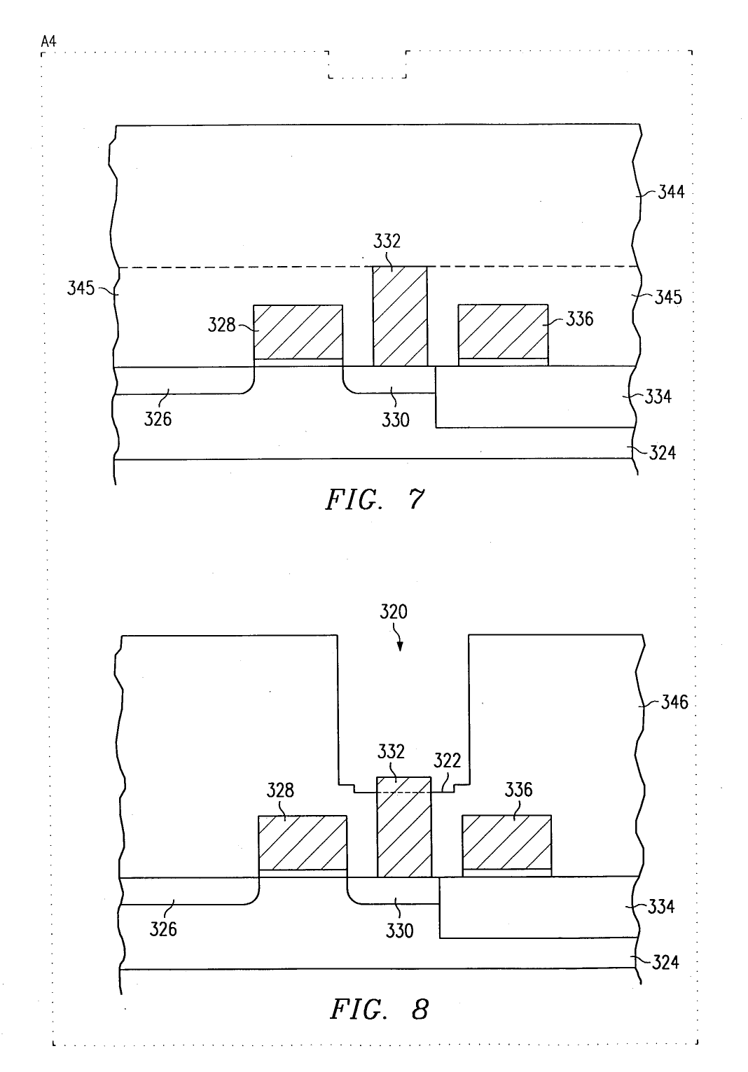

As shown in FIG. 7, a second level 344 of the PMD layer is deposited on the planarized first level 345 of the PMD layer.

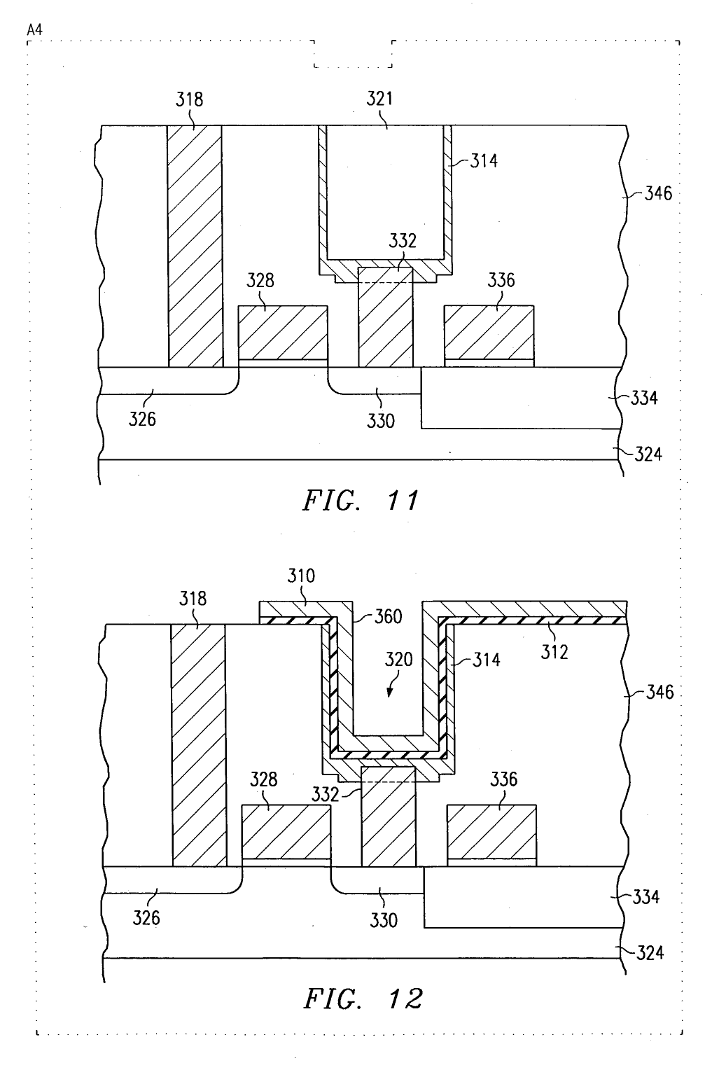

As shown in FIG. 8, capacitor well 320 is formed in the PMD layer 346 (which is the combination of first level 345 and second level 344 of the PMD material). The capacitor well 320 is patterned and etched in PMD layer 346. Preferably, the combined PMD layer 346 approximates a desired logic process flow dielectric thickness for a first metal layer. Capacitor well 320 is etched down to a lower limit 322. Preferably, the lower limit 322 of the capacitor well 320 is located below an upper end of contact 332. Thus, the lower limit 322 of the capacitor well 320 is disposed between the first end and second end of contact 332, where the first end of contact 332 is in contact with the second conductive element 330, and the second end of contact 332 extends into capacitor well 320. It should be noted that the capacitor well 320 may be formed after patterning and etching the other contact 318 shown, for example, in FIG. 11.

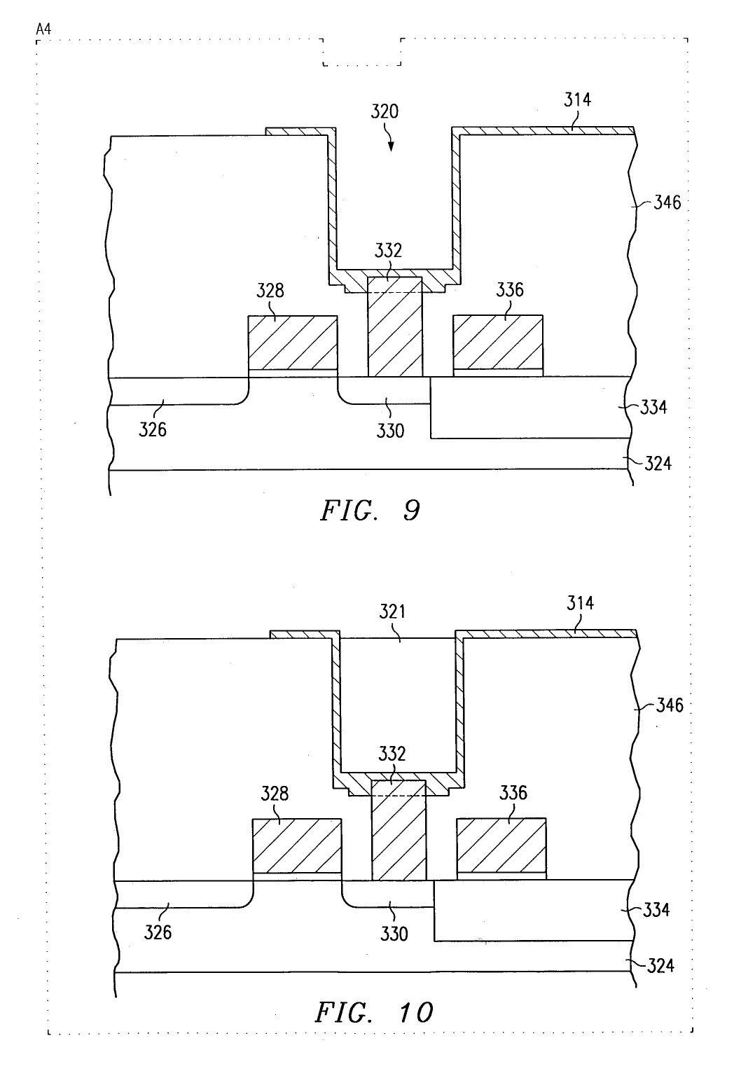

As shown in FIG. 9, a capacitor bottom plate 314 is formed in capacitor well 320. Preferably, capacitor bottom plate 314 conforms to the walls of capacitor well 320. Preferably, a portion of capacitor bottom plate 314 extends below the upper end of contact 332 to ensure a good connection.

As shown in FIG. 10, a dummy fill 321 is deposited in capacitor well 320 on capacitor bottom plate 314. Dummy fill 321 is preferably a material such as polyamide or paraline that is etch-selectable relative to the PMD dielectric. Dummy fill 321 and capacitor bottom plate 314 are then planarized.

As shown in FIG. 11, a contact 318 is patterned and etched in PMD layer 346. Contact 318 extends from a first end in contact with first conductive element 326 to a second end located approximately at the upper surface of PMD layer 346. Then, the contact material for contact 318 is planarized to a level substantially co-extensive with an upper surface of PMD layer 346.

As shown in FIG. 12, dummy fill 321 is removed from capacitor well 320. A capacitor dielectric layer 312 is formed on capacitor bottom plate 314. Preferably, a lower surface of capacitor dielectric layer 312 conforms to an upper surface of capacitor bottom plate 314. A capacitor top plate 310 is deposited on capacitor dielectric layer 312, for example, by patterning and etching. Capacitor top plate 310, capacitor dielectric layer 312, and capacitor bottom plate 314, cooperatively form capacitor structure 360. Preferably, the opening of capacitor well 320 and the thickness of capacitor structure 360 is such that capacitor well 320 is completely filled and capacitor top plate 310 presents a substantially planner top surface. Alternatively, if capacitor well 320 is not completely filled by capacitor structure 360 and capacitor top plate 310 has a depression (as illustrated in FIG. 12), the depression in capacitor top plate 310 may be filled before patterning and etching top plate 310. As an alternative, a CMP process can be used to remove capacitor top plate 310 and capacitor dielectric layer material from the top surface of the PMD layer without a patterned etch.

After the step shown in FIG. 12, other steps may be performed such as forming a first metal layer on the PMD layer 346 and on the capacitor structure 360 in order to complete the apparatus depicted, for example, in FIGS. 2 and 3. It will be apparent to those skilled in the art that this process may be modified to form other structures that incorporate contacts having multiple heights extending through a PMD layer.

Although the present invention has been described in detail, various changes and modifications may be suggested to one skilled in the art. As previously discussed, for example, contact 318 can be formed prior to formation of capacitor well 320. It is intended that the present invention encompass such changes and modifications as falling within the scope of the appended claims.

What is claimed is:

1. A semiconductor apparatus, comprising:
a substrate;
a first conductive element disposed in the substrate;
a second conductive element disposed in the substrate;
a pre-metal dielectric layer disposed on the substrate and having a capacitor well formed therein, the capacitor well extending from an upper limit to a lower limit;
a first contact extending within the pre-metal dielectric layer from the first conductive element to a level substantially coextensive with the upper limit of the capacitor well; and
a second contact extending within the pre-metal dielectric layer from the second conductive element at least to the lower limit of the capacitor well, wherein the second contact is shorter than the first contact.

2. The semiconductor apparatus of claim 1, the second contact extending from a first end in contact with the second conductive element to a second end, and wherein the lower limit of the capacitor well is at a level between the first and second ends of the second contact.

3. The semiconductor apparatus of claim 1, wherein the pre-metal dielectric layer has a thickness corresponding to a predetermined thickness for a pre-metal dielectric layer of a logic process flow adapted to incorporate the semiconductor apparatus.

4. The semiconductor apparatus of claim 1, the capacitor well having a height substantially the same as a height of the pre-metal dielectric layer.

5. The semiconductor apparatus of claim 1, wherein the first contact extends at least to substantially an upper limit of the pre-metal dielectric layer.

6. The semiconductor apparatus of claim 1, further comprising:
a first metal layer, wherein the first contact electrically connects the first conductive element to the first metal layer.

7. The semiconductor apparatus of claim 1, further comprising:
a first metal layer disposed on the pre-metal dielectric layer; and
a capacitor structure disposed at least partially within the capacitor well, wherein the capacitor structure is in contact with the first metal layer.

8. The semiconductor apparatus of claim 1, further comprising:
a first metal layer, the first contact extending from a first end in contact with the first conductive element to a second end in contact with the first metal layer;
an inter-level dielectric layer;
a second metal layer, the inter-level dielectric layer disposed between the first metal layer and the second metal layer; and
a via extending through the inter-level dielectric layer and electrically connecting the first metal layer with the second metal layer.

9. The semiconductor apparatus of claim 8, wherein a portion of the via extends from the first contact and through the first metal layer.

10. The semiconductor apparatus of claim 8, wherein the first metal layer is a bit line layer.

11. The semiconductor apparatus of claim 1, wherein the first contact and the second contact are formed from different materials.

12. The semiconductor apparatus of claim 1, wherein the first contact is formed from a pre-determined material, which corresponds to a contact material used in a logic process flow adapted to incorporate the semiconductor apparatus.

13. The semiconductor apparatus of claim 1, wherein the first contact is tungsten and the second contact is a form of silicon.

14. A semiconductor apparatus, comprising:
a substrate;
a first conductive element disposed in the substrate;
a second conductive element disposed in the substrate;
a pre-metal dielectric layer disposed on the substrate and having a capacitor well formed therein;
a first metal layer, the pre-metal dielectric layer being disposed between the substrate and the first metal layer;
a first contact extending from the first conductive element to the first metal layer; and
a second contact extending from the second conductive element at least to the capacitor well, wherein the second contact is shorter than the first contact.

15. The semiconductor apparatus of claim 14, wherein the first contact and the second contact are formed from different materials.

16. The semiconductor apparatus of claim 14, wherein the first contact is formed from a predetermined material, which corresponds to a contact material used in a logic process flow adapted to incorporate the semiconductor apparatus.

17. The semiconductor apparatus of claim 14, wherein the first contact is tungsten and the second contact is a form of silicon.

18. The semiconductor apparatus of claim 14, the second contact extending from a first end in contact with the second conductive element to a second end, and wherein a lower limit of the capacitor well is at a level between the first and second ends of the second contact.

19. The semiconductor apparatus of claim 14, wherein the pre-metal dielectric layer has a thickness corresponding to a predetermined thickness for a pre-metal dielectric layer of a logic process flow adapted to incorporate the semiconductor apparatus.

20. The semiconductor apparatus of claim 14, further comprising:
an inter-level dielectric layer;
a second metal layer, the inter-level dielectric layer disposed between the first metal layer and the second metal layer; and
a via extending through the inter-level dielectric layer and electrically connecting the first metal layer with the second metal layer.

21. The semiconductor apparatus of claim 20, wherein a portion of the via extends from the first contact and through the first metal layer.

22. The semiconductor apparatus of claim 14, wherein the first metal layer is a bit line layer.

23. A method of manufacturing a semiconductor apparatus, comprising:
providing a substrate;
forming a first conductive element in the substrate;
forming a second conductive element in the substrate;
providing a pre-metal dielectric layer on the substrate;
forming a capacitor well in the pre-metal dielectric layer;
providing a first metal layer on the pre-metal dielectric layer;
providing a first contact extending from the first conductive element to the first metal layer; and
providing a second contact extending from the second conductive element to at least a lower limit of the capacitor well, wherein the second contact is shorter than the first contact.

24. The method of claim 23, wherein the step of providing the first contact is accomplished prior to the step of forming the capacitor well.

25. The method of claim 23, wherein the step of providing the second contact is accomplished prior to the step of providing the first contact.

26. The method of claim 23, wherein the step of providing the pre-metal dielectric layer comprises forming a first level of the pre-metal dielectric layer and forming a second level of the pre-metal dielectric layer, and wherein the step of providing the second contact is accomplished after the step of forming the first level of the pre-metal dielectric layer and before the step of forming the second level of the pre-metal dielectric layer.

27. The method of claim 23, further comprising the steps of:
providing a capacitor bottom plate in the capacitor well;
providing a capacitor dielectric layer on the capacitor bottom plate;
providing a capacitor top plate on the capacitor dielectric layer;
and providing the first metal layer on the capacitor top plate.

28. The method of claim 27, wherein the second contact electrically connects the second conductive element with the capacitor bottom plate.

29. The method of claim 23, wherein the step of providing a pre-metal dielectric layer comprises depositing a dielectric material and planarizing the dielectric material with a chemical mechanical polish process.

30. The method of claim 29, wherein the step of providing a pre-metal dielectric layer further comprises further planarizing the dielectric material with an etch-back process.

31. The method of claim 23, wherein the step of providing a second contact comprises depositing a contact material and applying an etch-back process to the contact material.

32. The method of claim 23, wherein the step of providing the pre-metal dielectric layer comprises forming a first level of the pre-metal dielectric layer, wherein the method further comprises providing a layer of an etch-selectable material on the first level of the pre-metal dielectric layer, wherein the step of providing the second contact is accomplished after the step of providing the layer of an etch-selectable material, and wherein the method further comprises removing the etch-selectable material after the step of providing the second contact.
